(19) United States
(12) Patent Application Publication
(10) Pub. No.: US 2008/0296577 A1
(43) Pub. Date: Dec. 4, 2008

(54) Camera module package

(75) Inventors: Jingli Yuan, Suwon (KR); Won Kyu Jeung, Seoul (KR); Dae Jun Kim, Suwon (KR); Chang Hyun Lim, Suwon (KR); Jae Cheon Doh, Suwon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/155,268

(22) Filed: May 30, 2008

(30) Foreign Application Priority Data
May 31, 2007 (KR) 10-2007-0053553

(51) Int. Cl. H01L 31/00; H01L 21/02

(52) U.S. Cl. 257/59; 438/65; 257/E21.002; 257/E31.11; 257/E23.002

(57) ABSTRACT

There is provided a camera module package including: a substrate having an image sensor disposed on one surface thereof and a pad electrically connected to the image sensor; a protective cap adhered onto the substrate by an adhesive surrounding the image sensor to seal the image sensor, the protective cap transmitting light; and a supporting part surrounding the protective cap, the supporting part adhering and supporting at least one lens formed corresponding to the image sensor. The camera module package is reduced in thickness and size, and minimized in an error of a focal length between the lens and the image sensor, thereby achieving accuracy and high reliability.

### CROSS-REFERENCE TO RELATED APPLICATIONS

This application claims the priority of Korean Patent Application No. 2007-0053553 filed on May 31, 2007, in the Korean Intellectual Property Office, the disclosure of which is incorporated herein by reference.

### BACKGROUND OF THE INVENTION

1. Field of the Invention

The present invention relates to a camera module package including a substrate where an image sensor and a through electrode are formed and a protective cap and a lens disposed on the substrate.

2. Description of the Related Art

A sensor module such as a charge-coupled device (CCD) image sensor and a complementary metal-oxide semiconductor (CMOS) image sensor is utilized as a module for a conventional optical apparatus.

FIG. 1 is a cross-sectional view illustrating-configuration of a conventional camera module. The camera module of FIG. 1 includes a lens 10, a tubular-shaped housing 20 holding the lens and a circuit substrate 40. Also, the camera module includes a substrate 30, and an image sensor 32, a micro lens 34 and an electrode pad 36 formed on the substrate 30. A rear surface of the substrate 30 is die-bonded to the circuit substrate 40 by an adhesive 44, and the electrode pad 36 is electrically connected to a conductive circuit 42 formed on the circuit substrate 40 by a bonding wire 38.

The housing 20 has one opening sealed by a glass cover 12 and an adhesive 14 opposing the lens 10, and another opening sealed by the circuit substrate 40 and another adhesive 46. This allows the image sensor 32 and the micro lens 34 to be protected from external environment. Before the housing 20 is sealed, the image sensor 32 and the micro lens 34 need to be protected by other means.

The aforesaid camera module requires a space where the electrode pad 36 and the conductive wire 42 are connected together via the bonding wire 38. Moreover, the image sensor 32 is shielded from light and thus the bonding wire 38 and the electrode pad 36 cannot be disposed on the image sensor or the micro lens 34. In consequence, the conventional camera module is hardly miniaturizable. Besides, the housing having the lens attached thereon and the substrate having the image sensor disposed thereon are attached on the circuit substrate, respectively, thereby resulting in accumulation of tolerance. Therefore, an error in a focal length between the lens and the image sensor renders it hard to manufacture a precise camera module.

### SUMMARY OF THE INVENTION

An aspect of the present invention provides a more precise camera module package in which a lens is directly mounted on a substrate having a through electrode formed thereon to assure a smaller sized camera module package and minimize an error of a focal length between the lens and the image sensor.

According to an aspect of the present invention, there is provided a camera module package including: a substrate having an image sensor disposed on one surface thereof and a pad electrically connected to the image sensor; a protective cap adhered onto the substrate by an adhesive surrounding the image sensor to seal the image sensor, the protective cap transmitting light; and a supporting part surrounding the protective cap, the supporting part adhering and supporting at least one lens formed corresponding to the image sensor.

A micro lens may be disposed on a top of the image sensor.

The supporting part may be formed without interruption inside the pad.

The camera module package may further include a pad protection cap on a top of the pad.

The supporting part may be formed without interruption to cover a top of the pad.

The protective cap may have an infrared filter applied on one surface thereof.

The camera module package may further include a through electrode which is disposed in the device wafer connecting to the pad on one surface of the device wafer.

The camera module package may further include a external electrode on another surface of the device wafer connecting to the through electrode.

According to another aspect of the present invention, there is provided a method of manufacturing a camera module package, the method including: providing a base wafer having a protective cap disposed thereon; providing a device wafer having an image sensor disposed on one surface thereof to correspond to the protective cap, an adhesive formed around the image sensor and a pad electrically connected to the image sensor; adhering the protective cap onto the device wafer by the adhesive; forming a through electrode on one surface of the device wafer to connect to the pad and forming an external electrode on another surface of the device wafer to connect to the through electrode; bonding the device wafer and the lens wafer together on the one surface of the device wafer by a supporting part, the supporting part covering the pad and surrounding the protective cap; and dicing a camera module package including the image sensor into individual units.

The providing a base wafer may include bonding the protective cap on the one surface of the base wafer and removing a portion excluding the protective cap from the protective cap wafer.

The method may further include removing the base wafer, before the supporting part is provided.

The method may further include polishing the device wafer before the forming an external electrode.

According to still another aspect of the present invention, there is provided a method of manufacturing a camera module package, the method including: providing a base wafer having a protective cap and a pad protection cap disposed thereon; providing a device wafer having an image sensor disposed on one surface thereof to correspond to the protective cap, a pad formed on an area corresponding to the pad protection cap to electrically connect to the image sensor and an adhesive formed around the image sensor and on the pad, respectively; bonding the protective cap and the pad protection cap onto the device wafer by the adhesive; forming a through electrode on one surface of the device wafer to connect to the pad and forming an external electrode on another surface of the device wafer to connect to the through electrode; bonding the device wafer and the lens wafer onto the one surface of the device wafer by a supporting part, the supporting part formed without interruption between the protective cap and the pad protection cap; dividing the lens wafer into individual lenses to expose the pad protection cap to the outside; and dicing a camera module package including the image sensor into individual units.

The providing a base wafer may include bonding a protective cap wafer on the one surface of the base wafer and removing portions excluding the protective cap and the pad protection cap from the protection cap wafer.

The method may further include removing the base wafer before the supporting part is provided.

The method may further include polishing the device wafer before the forming an external electrode.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a conventional camera module package;

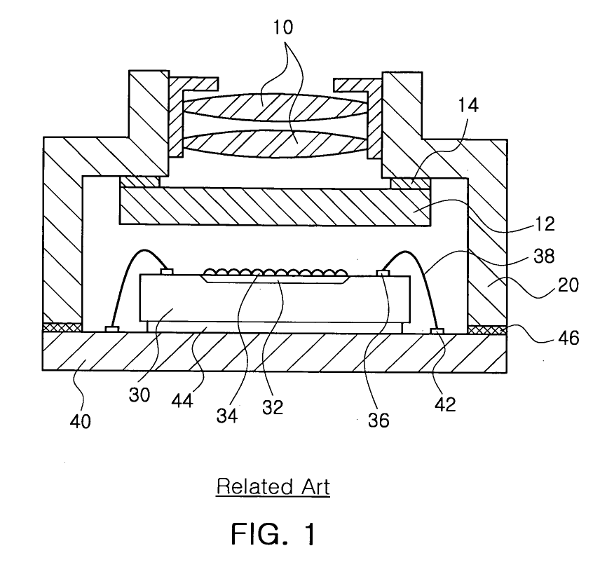

FIG. 2 is a cross-sectional view illustrating a camera module package according to an exemplary embodiment of the invention;

FIGS. 3A to 3E are procedural views illustrating a method of manufacturing a camera module package according to an exemplary embodiment of the invention;

FIG. 4 is a cross-sectional view illustrating a camera module package according to another exemplary embodiment of the invention; and

FIGS. 5A to 5F are procedural views illustrating a method of manufacturing a camera module package according to another exemplary embodiment of the invention.

### DETAILED DESCRIPTION OF THE PREFERRED EMBODIMENT

Exemplary embodiments of the present invention will now be described in detail with reference to the accompanying drawings.

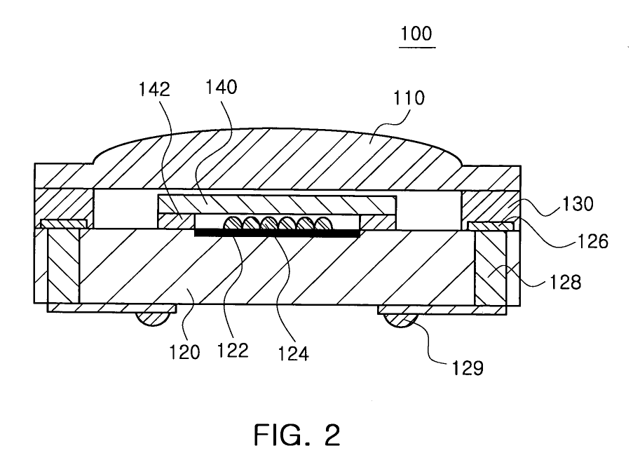

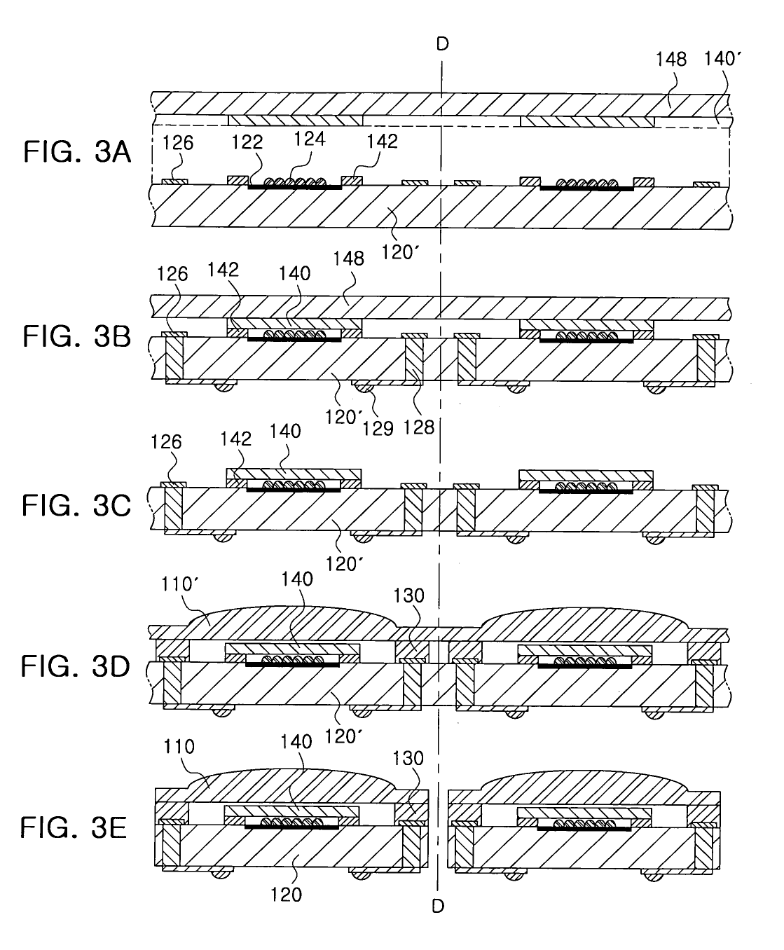

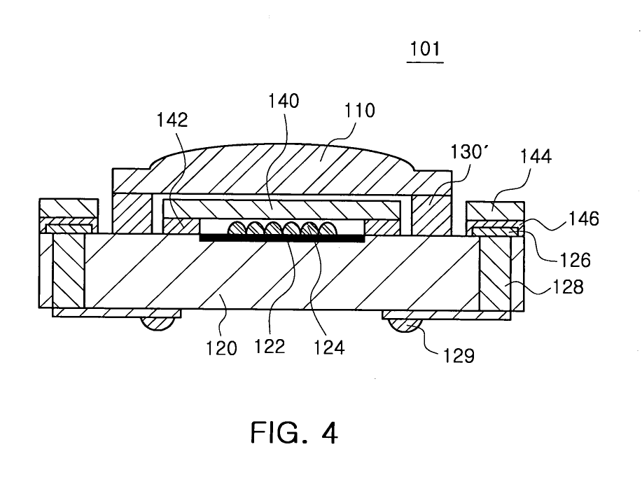

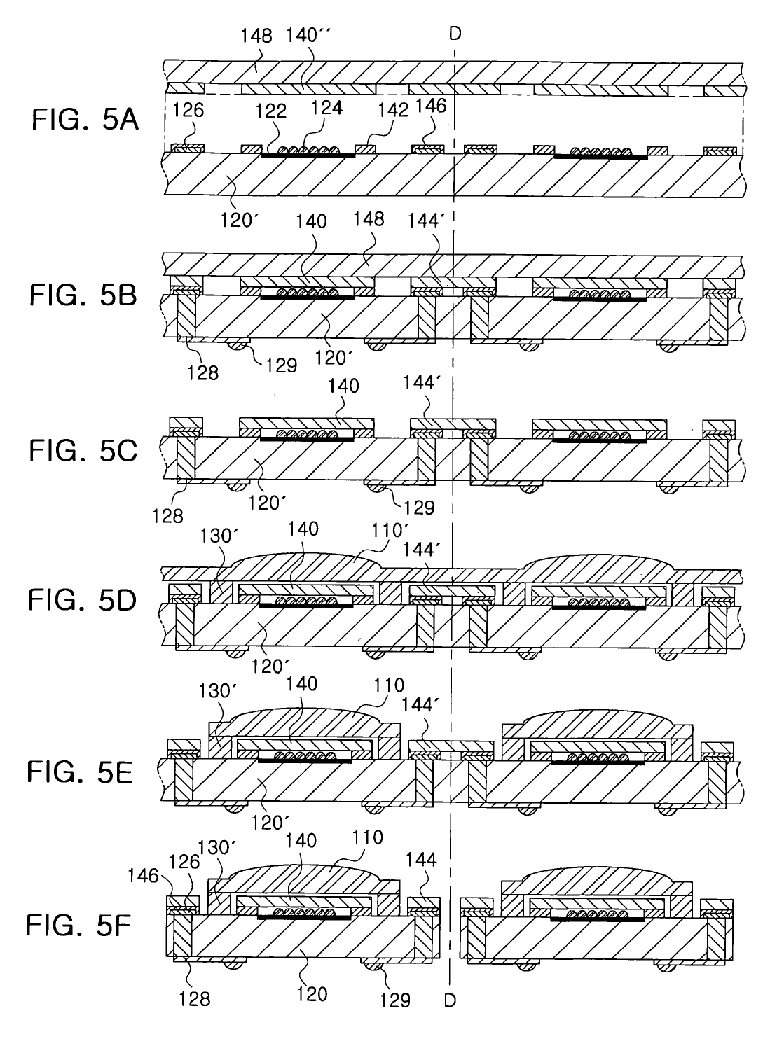

FIG. 2 is a cross-sectional view illustrating a camera module according to an exemplary embodiment of the invention. FIGS. 3A to 3D are procedural views illustrating a method of manufacturing a camera module package according to an exemplary embodiment of the invention. FIG. 4 is a cross-sectional view illustrating a camera module package according to another exemplary embodiment of the invention. FIGS. 5A to 5E are procedural views illustrating a method of manufacturing a camera module package according to another exemplary embodiment of the invention.

As shown in FIG. 2, the camera module package 100 of the present embodiment includes a lens 110, a substrate 120, a protective cap 140 and a supporting part 130.

The substrate 120 is provided on one surface thereof with an image sensor 122 imaging light passing through the lens 110 and converting the imaged light into an electrical signal. A pad 126 is disposed on an outer periphery of the image sensor 122 to connect to the image sensor 122 by an unillustrated pattern circuit.

A micro lens 124 is disposed on a top of the image sensor 122.

The protective cap 140 is bonded onto the substrate to cover the image sensor 122 by an adhesive 142 formed on the one surface of the substrate.

The adhesive 142 is applied without interruption along an edge of the image sensor 122.

The protective cap 140, when bonded on the one surface of the substrate by the adhesive 142, seals and protects the image sensor 122 and the micro lens 124 from external environment.

The protective cap 140 is a transparent member formed of a light transmissive material. For example, the protective cap 140 may be a glass substrate.

Also, an infrared (IR) filter (not shown) may be applied on one surface of the protective cap 140 to filter infrared rays of light passed through the lens 110.

This IR filter is disposed on a bottom of the protective cap 140 to correspond to the image sensor 122 and sealed by the adhesive 142 to be protected from external environment together with the image sensor 122.

The pad 126 is electrically connected to a through electrode 128 extending through the substrate 120.

The through electrode 128 is electrically connected to an external electrode 129 formed on another surface of the substrate 120, and the substrate 120 is bonded to a main substrate (not shown) by the external electrode 129.

The supporting part 130 is formed on the one surface of the substrate 120 to support the lens 110 as an adhesive bonding the lens 110 and the substrate 120 to each other.

The supporting part 130 surrounds the protective cap 140 above the pad 126, and is formed without interruption at a predetermined height.

The supporting part 130 has a height so as to be protruded higher than the protective cap 140. This prevents a bottom of the lens 110 from contacting a top of the protective cap 140.

An infrared image sensor (IRIS) (not shown) may be applied on a top of the lens 110 attached to the supporting part 130 to adjust incident light.

A method of manufacturing a camera module 100 according to an exemplary embodiment of the invention includes providing a base wafer having a protective cap thereon, providing a device wafer, bonding a protective cap and a device wafer together, forming an external electrode, bonding a device wafer and a lens wafer together, and dicing.

As shown in FIG. 3A, in providing the base wafer and the device wafer, the base wafer 148 has the protective cap 140 formed on one surface thereof, and the device wafer 120′ has an image sensor formed on one surface thereof to correspond to the protective cap. Also, a plurality of pads 126 are formed on an outer periphery of the image sensor 122 to connect to the image sensor 122 by a pattern circuit. An adhesive 142 is formed along an outer edge of the image sensor 122.

To form the protective cap 140, a protective cap wafer 140′ is bonded onto one surface of the base wafer 148 and then an area of the protective cap wafer 140′ excluding a portion corresponding to the image sensor 122, as indicated with a dotted line, is removed by etching, or half-dicing.

Here, the base wafer 148 may be a transparent silicon wafer and the protective cap wafer 140′ may be a glass wafer.

Also, a micro lens 124 is disposed on a top of the image sensor 122.

Next, in bonding the protective cap and the device wafer together, and forming the external electrode, as shown in FIG. 3B, the protective cap 140 is bonded to the device wafer 120′ by the adhesive 142 of the device wafer 120′. Also, a plurality of through electrodes 128 are formed to extend through the device wafer 120′ to electrically connect to the pads 126, respectively. External electrodes 129 are formed on another surface of the device wafer 120′ to connect to the through electrodes 128, respectively.

Each of the through electrodes 128 defines a via from the another surface of the device wafer 120′. The via is filled with a conductive material or has an inner surface applied with a conductive material.

Moreover, to reduce a height of the camera module, the device wafer 120′ may have the another surface thereof polished before the external electrodes 129 are formed.

After forming the external electrodes 129, as shown in FIG. 3C, the base wafer 148 is removed.

The base wafer 148 is removed by grinding, polishing, etching, thermal release, ultraviolet (UV) release and the like, while leaving only the protective cap 140.

Removal of the base wafer 148 is preceded by formation of the external electrodes 129, but the present embodiment is not limited thereto. The removal of the base wafer 148 can be performed as long as it is prior to forming a supporting part 130, which will be described later.

To bond the device wafer and the lens wafer together, as shown in FIG. 3D, the supporting part 130 is formed on one surface of the device wafer 120′ and the device wafer 120′ and the lens wafer 110′ are bonded together via the supporting part 130.

The lens wafer 110′ is a light transmissive wafer where a lens 110 is disposed corresponding to the image sensor 122 formed on the device wafer 120′.

The supporting part 130 is formed on the one surface of the device wafer 120′ to surround the protective cap 140 and be positioned over a top of each of the pads 126.

This supporting part 130 is applied at a predetermined height so as to be protruded higher than a top of the protective cap 140, thereby supporting the lens wafer 110′ at a predetermined distance from the image sensor 122.

The supporting part 130 may be formed with interruption. However, the supporting part 130 may be formed without interruption to prevent the lens 110 from tilting and accordingly an optical axis from being misaligned.

When dicing is performed, as shown in FIG. 3E, the lens wafer 110′ and the device wafer 120′ are diced along a virtual trimming line D into individual camera module packages 100.

Meanwhile, a camera module 101 according to another exemplary embodiment of the invention, as shown in FIG. 4, includes a lens 110, a substrate 120, a protective cap 140 and a supporting part 130′.

However, the same components as those in the camera module 100 of the previous embodiment will be designated with the same reference signs, and will be described in no more detail.

As shown in FIG. 4, pad protection caps 144 are formed on a top of a pad 126 disposed on one surface of a substrate 120 by an adhesive 146.

The pad protection caps 144 cover pads 126, respectively to protect the pads 126 from external environment, and may be formed of a material identical to that of the protective cap 140.

The supporting part 130′ is formed without interruption on the one surface of the substrate 120 to surround the protective cap 140 between the protective cap 140 and the pad protection caps 144. The supporting part 130′ supports the lens 110 and bonds the lens 110 and the substrate 120 together.

A method of manufacturing a camera module 101 according to another exemplary embodiment of the invention includes providing a base wafer having a protective cap and pad protection caps thereon, providing a device wafer, bonding the protective cap and the pad protection cap on the device wafer, forming an external electrode, bonding the device wafer and the lens wafer together, removing the lens wafer, and dicing.

As shown in FIG. 5A, when providing the base wafer and the device wafer, the base wafer 148 has the protective cap 140 and the pad protection caps 144′ formed thereon. The device wafer 120′ has an image sensor 122 formed on one surface thereof to correspond to the protective cap 140. Also, a plurality of pads 126 are formed on an outer periphery of the image sensor 122 to correspond to the pad protection caps 144′, respectively.

To form the protective cap 140 and the pad protection caps 144′, a protective wafer 140″ is bonded onto one surface of the base wafer 148 and then an area of the protective wafer 140″ excluding portions corresponding to the protective cap 140 and the pad protection caps 144′, as indicated with a dotted line, is removed by etching.

Here, the base wafer 148 may be a transparent silicon wafer and the protective wafer 140″ may be a glass wafer.

Also, an adhesive 146 is formed on the outer periphery of the image sensor 122 and a top of each of the pads 126 on the one surface of the device wafer 120′.

Moreover, a micro lens 124 is disposed on a top of the image sensor 122.

When bonding the protective cap and the pad protection caps to the device wafer and forming the external electrode, as shown in 5B, the protective cap 140 and the pad protection caps 144′ are bonded together by the adhesives 142 and 146.

In addition, a plurality of through electrodes 128 are formed to extend through the device wafer 120′ and to electrically connect to the pad 126. External electrodes 129 are formed on another surface of the device wafer 120′ to connect to the plurality of through electrodes 128, respectively.

The through electrodes 128 define a via from the another surface of the device wafer 120′. The via is filled with a conductive material or has an inner surface applied with a conductive material.

To reduce a height of the camera module, the device wafer 120′ may have the another surface polished before the external electrodes 129 are formed.

After forming the external electrodes 129, as shown in FIG. 5C, the base wafer 148 is removed.

To remove the base wafer 148, the base wafer 148 is polished by grinding or polishing, while leaving the protective cap 140 and the pad protection caps 144′.

Removal of the base wafer 148 is preceded by formation of the external electrodes 129, but the present embodiment is not limited thereto. The removal of the base wafer 148 can be performed as long as it is prior to forming supporting parts 130′, which will be described later.

To bond the device wafer and the lens wafer together, as shown in FIG. 5D, the supporting parts 130′ are formed on the one surface of the device wafer 120′, and the device wafer 120′ and the lens wafer 110′ are bonded together via the supporting part 130′.

The lens wafer 110′ is a light transmissive wafer where a lens 110 is disposed corresponding to the image sensor 122 formed on the device wafer 120′.

The supporting parts 130′ are applied as an adhesive on the one surface of the device wafer 120′ to surround the protective cap 140 between the protective cap 140 and the pad protection caps 144′.

This supporting part 110′ is applied at a predetermined height so as to be protruded higher than a top of the protective cap 140, thereby supporting the lens wafer 110′ at a predetermined distance from the image sensor 122.

The supporting parts 130′ may be formed with interruption. However, the supporting parts 130′ may be formed without interruption to prevent the lens 110 from tilting and accordingly an optical axis from being misaligned.

When the lens wafer is divided, as shown in FIG. 5E, an adjacent portion between the supporting parts 130′ is removed from the lens wafer 110′ by dry etching or half-dicing.

This allows the lens wafer 110′ to be divided into individual lenses 110 and the pad protection caps 144′ to be exposed outward.

When dicing is performed, as shown in FIG. 5F, the pad protection caps 144′ and the device wafer 120′ are diced along a virtual trimming line D into individual camera module packages 101.

In consequence, the camera module has the lens directly attached on the substrate to be minimized in height and also minimized in errors of a focal length between the lens and the image sensor resulting from tolerance of the adhesive.

As set forth above, a camera module package according to exemplary embodiments of the invention has a lens directly attached on a substrate to be reduced in thickness and size. Also, the camera module package has only a supporting part disposed between the lens and the substrate to ensure minimal errors of a focal length between the lens and the image sensor. This allows for a more precise and more highly reliable camera module package.

While the present invention has been shown and described in connection with the exemplary embodiments, it will be apparent to those skilled in the art that modifications and variations can be made without departing from the spirit and scope of the invention as defined by the appended claims.

What is claimed is:

1. A camera module package comprising:
a substrate having an image sensor disposed on one surface thereof and a pad electrically connected to the image sensor;
a protective cap adhered onto the substrate by an adhesive surrounding the image sensor to seal the image sensor, the protective cap transmitting light; and
a supporting part surrounding the protective cap, the supporting part adhering and supporting at least one lens formed corresponding to the image sensor.

2. The camera module package of claim 1, wherein a micro lens is disposed on a top of the image sensor.

3. The camera module package of claim 1, wherein the supporting part is formed without interruption inside the pad.

4. The camera module package of claim 3, further comprising a pad protection cap on a top of the pad.

5. The camera module package of claim 1, wherein the supporting part is formed without interruption to cover a top of the pad.

6. The camera module package of claim 1, wherein the protective cap has an infrared filter applied on one surface thereof.

7. The camera module package of claim 1, further comprising a through electrode which is disposed in the device wafer connecting to the pad on one surface of the device wafer.

8. The camera module package of claim 7, further comprising an external electrode on another surface of the device wafer connecting to the through electrode.

9. A method of manufacturing a camera module package, the method comprising:
providing a base wafer having a protective cap disposed thereon;
providing a device wafer having an image sensor disposed on one surface thereof to correspond to the protective cap, an adhesive formed around the image sensor and a pad electrically connected to the image sensor;
adhering the protective cap onto the device wafer by the adhesive;
forming a through electrode on one surface of the device wafer to connect to the pad and forming an external electrode on another surface of the device wafer to connect to the through electrode;
bonding the device wafer and the lens wafer together on the one surface of the device wafer by a supporting part, the supporting part covering the pad and surrounding the protective cap; and
dicing a camera module package including the image sensor into individual units.

10. The method of claim 9, wherein the providing a base wafer comprises bonding the protective cap on the one surface of the base wafer and removing a portion excluding the protective cap from the protective cap wafer.

11. The method of claim 9, further comprising removing the base wafer, before the supporting part is provided.

12. The method of claim 9, further comprising polishing the device wafer before the forming an external electrode.

13. A method of manufacturing a camera module package, the method comprising:
providing a base wafer having a protective cap and a pad protection cap disposed thereon;
providing a device wafer having an image sensor disposed on one surface thereof to correspond to the protective cap, a pad formed on an area corresponding to the pad protection cap to electrically connect to the image sensor and an adhesive formed around the image sensor and on the pad, respectively;
bonding the protective cap and the pad protection cap onto the device wafer by the adhesive;
forming a through electrode on one surface of the device wafer to connect to the pad and forming an external electrode on another surface of the device wafer to connect to the through electrode;
bonding the device wafer and the lens wafer onto the one surface of the device wafer by a supporting part, the supporting part formed without interruption between the protective cap and the pad protection cap;
dividing the lens wafer into individual lenses to expose the pad protection cap to the outside; and
dicing a camera module package including the image sensor into individual units.

14. The method of claim 13, wherein the providing a base wafer comprises bonding a protective cap wafer on the one surface of the base wafer and removing portions excluding the protective cap and the pad protection cap from the protection cap wafer.

15. The method of claim 13, further comprising removing the base wafer before the supporting part is provided.

16. The method of claim 13, further comprising polishing the device wafer before the forming an external electrode.
